(19) United States
(12) Patent Application Publication
(10) Pub. No.: US 2021/0202333 A1
(43) Pub. Date: Jul. 1, 2021

(54) ENCAPSULATION STRUCTURE

(71) Applicant: Industrial Technology Research Institute, Hsinchu (TW)

(72) Inventors: Hong-Ming DAI, Tainan City (TW); Jane-Hway LIAO, Hsinchu County (TW); Yen-Ching KUO, Keelung City (TW); Shu-Tang YEH, Taichung City (TW); Wei-Lung TSAI, Tainan City (TW); Hung-Yi CHEN, New Taipei City (TW); Chien-Chang HUNG, Hsinchu City (TW)

(21) Appl. No.: 15/931,525

(22) Filed: May 13, 2020

(30) Foreign Application Priority Data
Dec. 30, 2019 (TW) 108148330

(51) Int. Cl. H01L 23/29; H01L 23/31

(52) U.S. Cl. CPC H01L 23/291; H01L 23/3135

(57) ABSTRACT

An encapsulation structure may include a flexible substrate, a plurality of electronic elements, a first partition wall, a second partition wall, and a gas barrier layer. The flexible substrate has a device region and a non-device region. The electronic elements are disposed in the device region of the flexible substrate. The first partition wall surrounds one or more of the electronic elements. The second partition wall surrounds the first partition wall. There is at least one trench between the first partition wall and the second partition wall. The gas barrier layer covers one or more of the electronic elements and the surface of the first partition wall. The surface of the first partition wall has a higher surface energy than the surface of the second partition wall.

### CROSS REFERENCE TO RELATED APPLICATIONS

The present application is based on, and claims priority from, Taiwan Application Serial Number 108148330, filed on Dec. 30, 2019, the disclosure of which is hereby incorporated by reference herein in its entirety.

### TECHNICAL FIELD

The technical field relates to an encapsulation structure, and in particular it relates to an encapsulation structure containing a gas barrier layer.

### BACKGROUND

As the technology used in the electronic element industry advances, electronic elements continue to evolve from having rigid and inflexible characteristics to having soft and flexible characteristics. This development has accompanied a change in the materials used in electronic elements. For example, rigid glass substrates have largely been replaced with flexible substrates in many applications. Flexible materials, including some organic materials, are also gradually being developed for use as various components in electronic elements. When flexible electronic elements are made of organic materials, their ability to block moisture and oxygen is always an issue that has to be addressed. In order to efficiently extend the lifespan of flexible electronic elements, various encapsulation structures focus on technical means to restrict the ingress of moisture and oxygen.

If an entire layered barrier layer is used to cover all the electronic elements on the flexible substrate, the flexibility of the flexible substrate will suffer. On the other hand, if the entire layered gas barrier layer is too thin, it cannot provide moisture and gas resistance. If the entire layered gas barrier layer is too thick, the substrate will lose flexibility, or the entire layered gas barrier layer will break when flexed, canceling its effectiveness as a gas barrier. Accordingly, a novel structure design is called for to simultaneously provide flexibility to the flexible substrate and maintain the gas-barrier properties of the gas barrier layer.

### SUMMARY

One embodiment of the disclosure provides an encapsulation structure, including a flexible substrate, a plurality of electronic elements, a first partition wall, a second partition wall, and a first gas barrier layer. The flexible substrate has a device region and a non-device region. The electronic elements are disposed in the device region of the flexible substrate. The first partition wall surrounds one or more of the electronic elements. The second partition wall surrounds the first partition wall. There is at least one trench between the first partition wall and the second partition wall. The first gas barrier layer covers one or more of the electronic elements and the surface of the first partition wall. The surface of the first partition wall has a higher surface energy than the surface of the second partition wall.

One embodiment of the disclosure provides an encapsulation structure, including: a flexible substrate; a plurality of electronic elements located on the flexible substrate; a first gas barrier layer covering sidewalls and a top surface of one or more of the electronic elements; and a flexible structure located on the flexible substrate. The first gas barrier layer is disposed between the flexible structure and one or more of the electronic elements, and the flexible structure has a Young's modulus of greater than or equal to 0.2 GPa and less than 2 GPa.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1 to 6 show cross-sectional views of encapsulation structures in embodiments of the disclosure.

FIGS. 7A to 7E, 8A to 8E, 9A to 9E, 10A to 10E, 11A to 11E, 12A to 12E, 13A to 13E, 14A to 14E, 15A to 15E, 16A to 16E, 17A and 17E, and 18A to 18E show cross-sectional views of the intermediate stages of a process for fabricating the encapsulation structures.

### DETAILED DESCRIPTION

In the following detailed description, for purposes of explanation, numerous details are set forth in order to provide a thorough understanding of the disclosed embodiments. It will be apparent, however, that one or more embodiments may be practiced without these details. In other instances, well-known structures and devices are schematically shown in order to simplify the drawing.

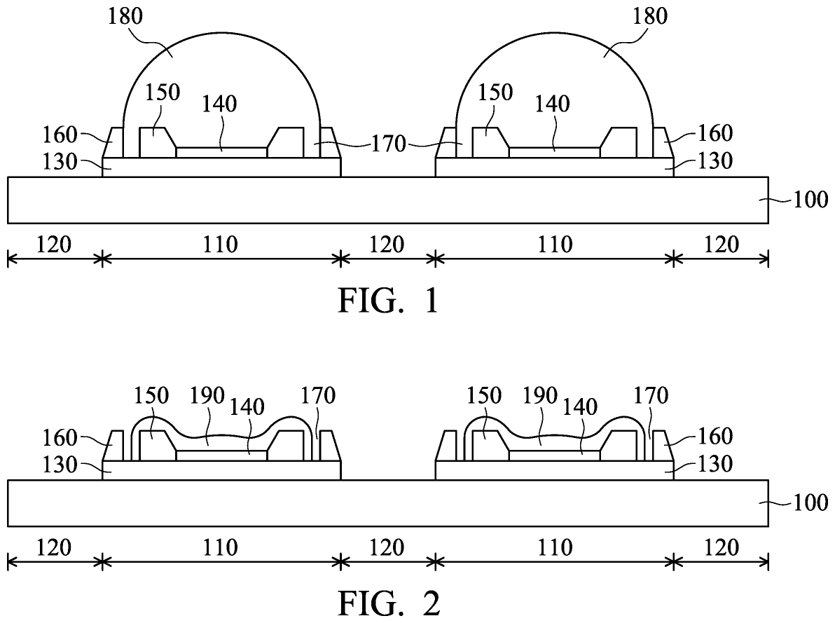

One embodiment of the disclosure provides an encapsulation structure, as shown in FIG. 1. In FIG. 1, the flexible substrate 100 includes a device region 110 and a non-device region 120. In FIG. 1, the device 130 of the device region 110 is higher than the flexible substrate 100. However, it should be understood that the device 130 can be embedded in the flexible substrate 100, such that the top surface of the device 130 can be lower than or coplanar with the top surface of the flexible substrate 100. For example, the flexible substrate 100 can be composed of polyimide, silicone, or polycarbonate, and may have a Young's modulus of 0.1 GPa to 20 GPa. In general, the device 130 may include active device (such as transistor, memory device, or the like), passive device (such as capacitor, resistor, inductor, or the like), or a combination thereof. The flexible substrate 100 may include interconnect structure such as line or via, which may electrically connect the devices in different device regions 110 to form a functional circuit.

As shown in FIG. 1, the electronic element 140 is disposed on the device 130, such as disposed in the device region 110 of the flexible substrate 100. In one embodiment, the electronic element 140 can be electroluminescence (EL) or quantum dot (QD). Take a three color light-emitting device as example, one pixel may include sub-pixels such as red light-emitting diode, green light-emitting diode, and blue light-emitting diode, and the electronic element 140 can be regarded as one sub-pixel of the pixel.

As shown in FIG. 1, a first partition wall 150 surrounds a single electronic element 140. Note that even the first partition wall 150 surrounds the single electronic element 140 in FIG. 1, the first partition wall 150 may surround a row or a column (e.g. 1×n or n×1) of the electronic elements 140. Alternatively, the first partition wall 150 may surround a block (e.g. n×n) of the electronic elements 140. For example, the first partition wall 150 may surround the electronic elements 140 of one pixel region, such as the electronic elements 140 of three sub-pixel regions.

As shown in FIG. 1, a second partition wall 160 surrounds the first partition wall 150, and the first partition wall 150 and the second partition wall 160 have a trench 170 therebetween. In one embodiment, the trench 170 may not completely penetrate through as shown in FIG. 1 to expose the surface of the device 130, and the first partition wall 150 and the second partition wall 160 may have gas barrier property to prevent moisture and oxygen from entering the electronic element 140 through the sides. The height of the first partition wall 150 can be equal to the height of the second partition wall 160. The surface energy of the first partition wall 150 can be higher than the surface energy of the second partition wall 160. In one embodiment, the surface energy of the first partition wall 150 is higher than the surface energy of the second partition wall 160 by 5 mN/m to 40 mN/m. If the difference between the surface energy of the first partition wall 150 and the surface energy of the second partition wall 160 is too small, the solution 180 described below may overflow out of the second partition wall 160 and into the non-device region 120 of the flexible substrate 100. If the difference between the surface energy of the first partition wall 150 and the surface energy of the second partition wall 160 is too large, it will not be easy to cover the first partition wall 150 with the coating.

In one embodiment, the first partition wall 150 and the second partition wall 160 are formed by a patterning process such as inkjet coating process, lithography and etching process, or the like. After forming the first partition wall 150 and the second partition wall 160, a shadow mask is used to expose the surface of the first partition wall 150 for being surface treated by IR direct writing or oxygen plasma. As such, the surface energy of the first partition wall 150 is higher than the surface energy of the second partition wall 160. On the other hand, the surface of the second partition wall 160 can be exposed by a shadow mask and treated by argon or nitrogen plasma, such that the surface energy of the first partition wall 150 is greater than the surface energy of the second partition wall 160. In addition, the first partition wall 150 can be firstly formed, and the surface of the first partition wall 150 is then modified by UV, plasma, IR, or chemicals. The second partition wall 160 is then formed, such that the surface energy of the modified surface of the first partition wall 150 is higher than the surface energy of the second partition wall 160. On the other hand, the first partition wall 150 and the second partition wall 160 can be made of different materials, and the surface energy of the first partition wall 150 is higher than the surface energy of the second partition wall 160. For example, the first partition wall 150 can be composed of polysilazane, epoxy resin, novolac resin, or the like, and the second partition wall 160 can be composed of silicon oxynitride, acrylic, polyurethane, or the like. The first partition wall 150 and the second partition wall 160 can be made of different materials, and the surface of the first partition wall 150 (or the second partition wall 160) can be further modified by UV, plasma, IR, or chemicals.

In some embodiments, the first partition wall 150 has a height of 0.1 μm to 5 μm. If the height of the first partition walls 150 is too low, the solution 180 may overflow out of the second partition wall 160 and into the non-device region 120 of the flexible substrate 100. If the height of the first partition wall 150 is too high, it will be difficult to completely encapsulate and the gas-barrier effect will fail at the sides. In some embodiments, the trench 170 has a width of 0.1 μm to 500 μm. If the width of the trench 170 is too small, the overflow of the solution will be difficult to block. If the width of the trench 170 is too large, it will easily form a weak region in the device.

As shown in FIG. 1, the solution covers the electronic element 140 and the first partition wall 150, and the solution 180 may fill the trench 170. The solution 180 can be applied by coating, such as spin-on coating, blade coating, slit coating, dip coating, inkjet coating, screen-printing, or the like. In one embodiment, the solution 180 can be composed of polysilazane, silicon oxynitride, or the like. Because the surface energy of the first partition wall 150 is higher than the surface energy of the second partition wall 160, it may prevent the solution 180 from following issues: overflowing out of the second partition wall 160, covering the surface of the flexible substrate 100 out of the second partition wall 160 (e.g. the surface of the non-device region 120), and lowering the flexibility of the encapsulation structure.

Subsequently, the solution 180 is dried and surface treated to form a gas barrier layer 190 covering the surface of the electronic elements 140 and the first partition wall 150, as shown in FIG. 2. The surface treatment includes light irradiation, heating, or plasma treatment, and the like. The exposed surface of the gas barrier layer 190 is modified to be more compact, thereby improving the barrier properties of the gas barrier layer 190. In addition, the plasma treated surface of the gas barrier layer 190 may further include a doping element. The doping element can be gas component used in plasma, which may include argon, hydrogen, nitrogen, oxygen, inert gas element, or a combination thereof. In some embodiments, the content of the doping element in the gas barrier layer 190 can be greater than 0 atomic % to 5 atomic %. The gas barrier layer 190 may completely seal the surface of the first partition wall 150 and the surface of the electronic element 140, which may avoid the moisture and/or oxygen entering the electronic elements 140 from the side of the first partition wall 150. Note that the gas barrier layer 190 may cover a part of the surface of the first partition wall 150, but the gas barrier layer 190 may also cover the bottom of the trench 170 and even a part of the surface of the second partition wall 160 in the trench 170. In one embodiment, the thickness of the gas barrier layer 190 on the electronic element 140 and the height of the first partition wall 150 may have a ratio of 0.02:1 to 1:1. If the thickness of the gas barrier layer 190 is too small, the effect of blocking moisture and oxygen may not be achieved. If the thickness of the gas barrier layer 190 is too large, initial amount of the solution 180 will be too much and exceed the capacity of the space that is surrounded by the first partition wall 150 and the trench 170, such that the solution 180 will overflow out of the second partition wall 160.

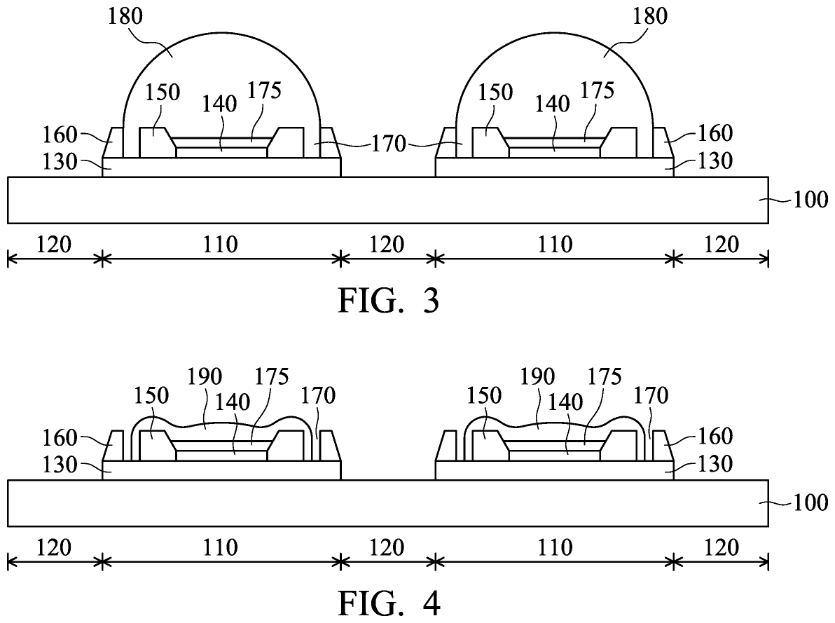

As shown in FIG. 3, the buffer layer 175 can be formed on the electronic element 140 before forming the solution 180 if the solution 180 damages the electronic element 140. The buffer layer 175 may fill and cover the defects to protect the electronic element 140 from the influence of the solution 180. In one embodiment, the buffer layer 175 can be composed of acrylic acid resin, epoxy resin, novolac resin, or the like. After forming the solution 180, the solution 180 is dried and surface treated to form the structure as shown in FIG. 4. In FIG. 4, the buffer layer 175 is disposed between the electronic element 140 and the gas barrier layer 190. In one embodiment, the thickness of the buffer layer 175 and the height of the first partition wall 150 may have a ratio of 0.5:1 to 0.98:1. If the thickness of the buffer layer 175 is too large, the amount of the solution 180 will be reduced, and thickness of the gas barrier layer 190 formed by drying the solution 180 will be insufficient. If the buffer layer 175 is too thin, it may not prevent the electronic elements 140 from being damaged by the solution 180. In one embodiment, the total thickness of the buffer layer 175 and the gas barrier layer 190 and the height of the first partition wall 150 have a ratio of 0.52:1 to 1:1. If the total thickness of the buffer layer 175 and the gas barrier layer 190 is too small, this cannot achieve the effect of blocking moisture and/or oxygen. If the total thickness of the buffer layer 175 and the gas barrier layer 190 is too large, the initial amount of the solution 180 will be too much and exceed the capacity of the space that is surrounded by the first partition wall 150 and the trench 170, such that the solution 180 will overflow out of the second partition wall 160. The buffer layer 175 not only protects the electronic element 140 from being damaged by the solution 180, but also blocks moisture and/or oxygen to enter the electronic elements 140. However, the buffer layer 175 assists and the gas barrier layer 190 cannot be omitted.

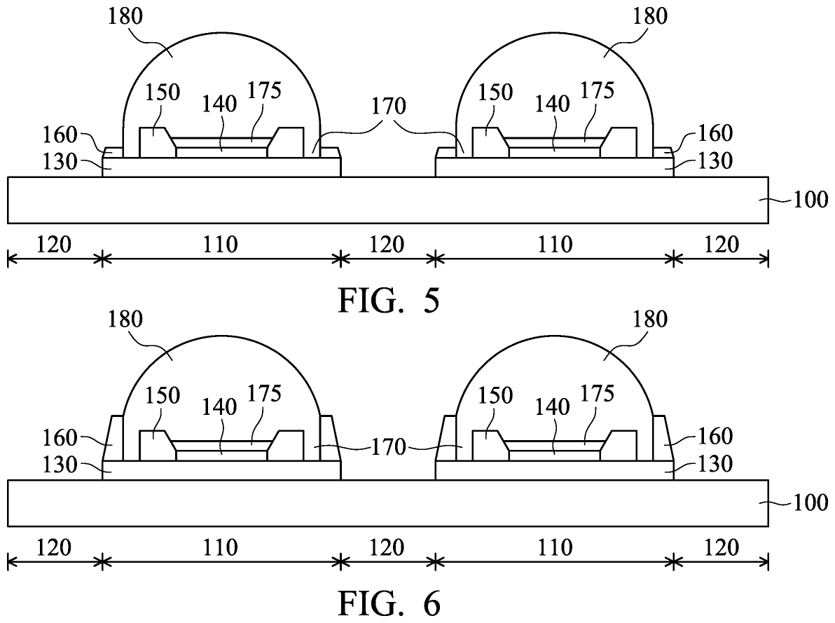

In one embodiment, the first partition wall 150 can be higher than the second partition wall 160, as shown in FIG. 5. Alternatively, the first partition wall 150 can be lower than the second partition wall 160, as shown in FIG. 6. Note that although the buffer layer 175 is formed on the electronic element 140 in FIGS. 5 and 6, the buffer layer 175 can be optionally omitted and the solution 180 may directly contact the electronic device. Thereafter, the solution 180 in FIGS. 5 and 6 can be dried and surface treated to form a gas barrier layer 190 (not shown). Whatever the second partition wall 160 are higher or lower than the first partition wall 150, the gas barrier layer 190 covers the surface of the electronic elements 140 (or the optional buffer layer 175) and the first partition wall 150. The gas barrier layer 190 may cover the bottom of the trenches 170, and even covers the surface of the second partition wall 160 in the trenches 170.

In one embodiment, the second partition wall 160 can be flexible structure. For example, the second partition wall 160 has a Young's modulus of greater than or equal to 0.2 GPa and less than 2 GPa. The flexible structure is beneficial to improve the flexibility of the encapsulation structure. On the other hand, the surface energy flexible structure (e.g. the second partition wall 160) is lower than the surface energy of the first partition wall 150, as described above. In some embodiments, the flexible structure can be composed of silicone, acrylic-based polymer, polyurethane, epoxy resin, or the like, and the flexible structure can be formed by coating, deposition, or evaporation.

In the above figures, the first partition wall 150 may surround the single electronic element 140. As such, a top view area that is covered by the gas barrier layer 190 and the total area of the device region 110 and the non-device region 120 have a ratio of greater than 0.01 and less than 0.32. Note that even the first partition wall 150 surrounds the single electronic element 140 in FIG. 1, the first partition wall 150 may surround a row or a column (e.g. 1×n or n×1) of the electronic elements 140. Alternatively, the first partition wall 150 may surround a block (e.g. n×n) of the electronic elements 140. For example, the first partition wall 150 may surround the electronic elements 140 of one pixel region, such as the electronic elements 140 of three sub-pixel regions. In one embodiment, the first partition wall 150 surrounds one pixel, and a top view area that is covered by the gas barrier layer 190 and the total area of the device region 110 and the non-device region 120 have a ratio of greater than 0.45 and less than 0.97. In one embodiment, the first partition wall 150 surrounds many pixels, and a top view area that is covered by the gas barrier layer 190 and the total area of the device region 110 and the non-device region 120 have a ratio of greater than 0.7 and equal to or less than 0.97. It should be understood that the first partition wall 150 does not surround all the electronic elements 140. If all the electronic elements 140 are surrounded by the first partition wall 150, a top view area that is covered by the gas barrier layer 190 and the total area of the device region 110 and the non-device region 120 have a ratio of 1, which may not solve the problems in the prior art with the entire layered gas barrier layer (such as lowering the flexibility of the encapsulation structure, and the entire layered gas barrier layer breaking when flexed, negating its effectiveness as a gas barrier).

In one embodiment, the encapsulation structure includes a flexible substrate and a plurality of electronic elements on the flexible substrate. The encapsulation structure also includes a gas barrier layer covering sidewalls and the top surface of one or more of the electronic elements. The encapsulation structure also includes flexible structures on the flexible substrate, wherein the gas barrier layer is disposed between the flexible structure and one or more of the electronic elements. The flexible structure has a Young's modulus of greater than or equal to 0.2 GPa and less than 2 GPa. The flexible structures disposed on the flexible substrate may improve the flexibility of the encapsulation structure. The gas barrier layer covering electronic elements of different pixels or sub-pixels are not connected. In other words, the gas barrier layer does not cover the entire surface of the flexible substrate, which may not solve the problems in the prior art with the layered gas barrier layer (such as lowering the flexibility of the encapsulation structure, and the entire layered gas barrier layer breaking when flexed, negating its effectiveness as a gas barrier). In one embodiment, the flexible structure has a height of 0.1 μm to 5 μm and a width of 0.1 μm to 5 μm. If the height or width of the flexible structure is too large, the flexible structure will be difficult to completely encapsulate, and the gas barrier effect at the sides will fail. If the height or width of the flexible structure is too small, the flexible structure will be not easy to fabricate.

In one embodiment, the gas barrier layer may include a silicon oxynitride layer, a silicon nitride layer, or a multi-layered structure thereof.

In one embodiment, the encapsulation structure further includes a buffer layer disposed between layers of the multi-layered structure of the gas barrier layer, or disposed between the gas barrier layer and one or more of the electronic elements.

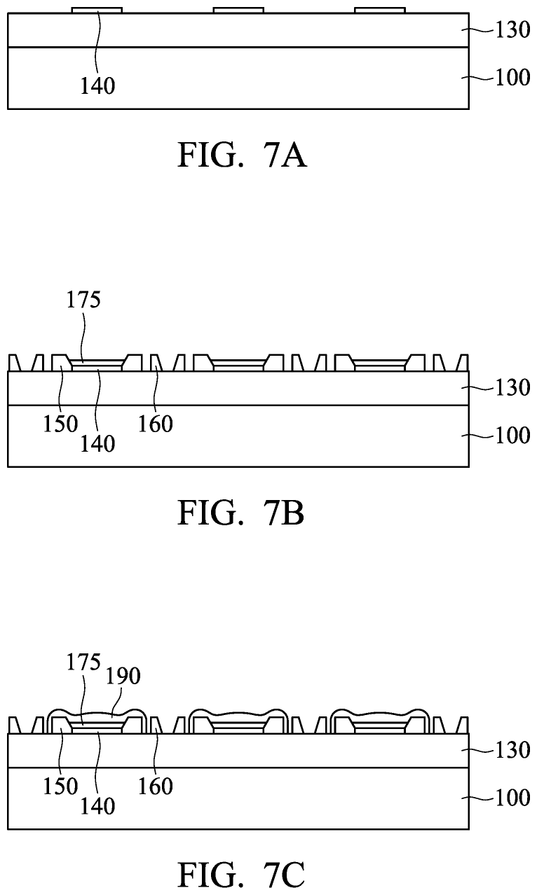

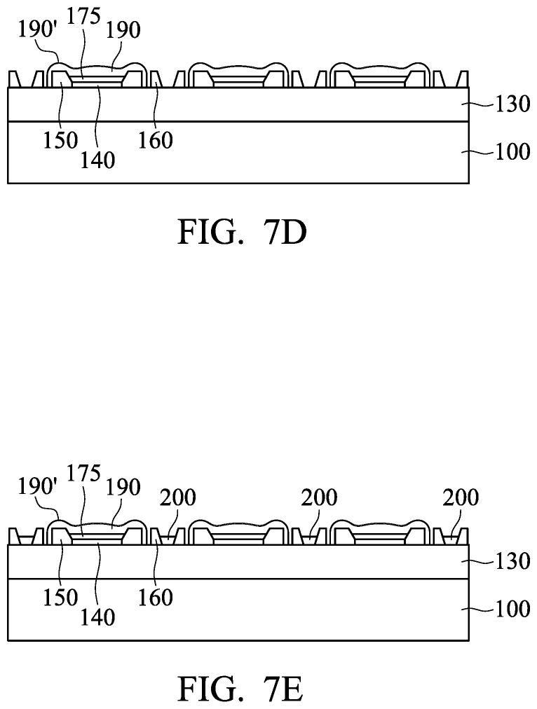

In one embodiment, an encapsulation structure is formed as shown in FIGS. 7A to 7E. As shown in FIG. 7A, a flexible substrate 100 is formed with a device 130 thereon. Although the device 130 in FIG. 7A is an entire layered structure, it can be separated structures such as the device 130 in FIG. 1. Electronic elements 140 are formed on the device 130. The details of the flexible substrate 100, the device 130, and the electronic elements 140 are similar to those described above, and the related description is not repeated here. As shown in FIG. 7B, first partition walls 150 and second partition walls 160 are formed, and the first partition walls 150 (or the second partition walls 160) are surface treated, such that the surface energy of the first partition walls 150 is different from the surface energy of the second partition walls 160. Subsequently, a buffer layer 175 is formed by a process such as inkjet printing to cover the electronic elements 140. As shown in FIG. 7C, a solution (such as the described solution 180) is then spray coated, dried, and surface treated to form a gas barrier layer 190 on the surface of the buffer layer 175 and the first partition walls 150. As shown in FIG. 7D, another solution (such as the described solution 180) can be selectively spray coated, dried, and surface treated to form another gas barrier layer 190′ on the surface of gas barrier layer 190. The gas barrier layer 190′ covering each of the gas barrier layer 190 is not connected, which does not cover the entire surface of the device 130. As shown in FIG. 7E, flexible structures 200 are then formed between the second partition walls 160 of different pixels or sub-pixels, thereby enhancing the flexibility of the encapsulation structure. It should be understood that the height of the flexible structures 200 can be higher than, equal to, or lower than the depth of the opening (between the second partition walls 160), as long as the flexibility of the encapsulation structure can be enhanced. Next, the flexible structures 200 may or may not contact the second partition walls 160 on the basis of requirements. Although one set of buffer layer 175/gas barrier layer 190/gas barrier layer 190′ covers the single electronic element 140 in the embodiment of FIGS. 7A to 7E, it may also cover a plurality of (not all) the electronic elements 140, as described above. On the other hand, the flexible structures 200 can be formed after surface treating the first partition walls 150 and/or the second partition walls 160, rather than formed after forming the gas barrier layer 190′. In addition, the second partition walls 160 may be flexible structures, so that the flexible structures 200 can be omitted. As such, the electronic elements 140 can be arranged more closely by freeing up the space occupied by the flexible structures 200.

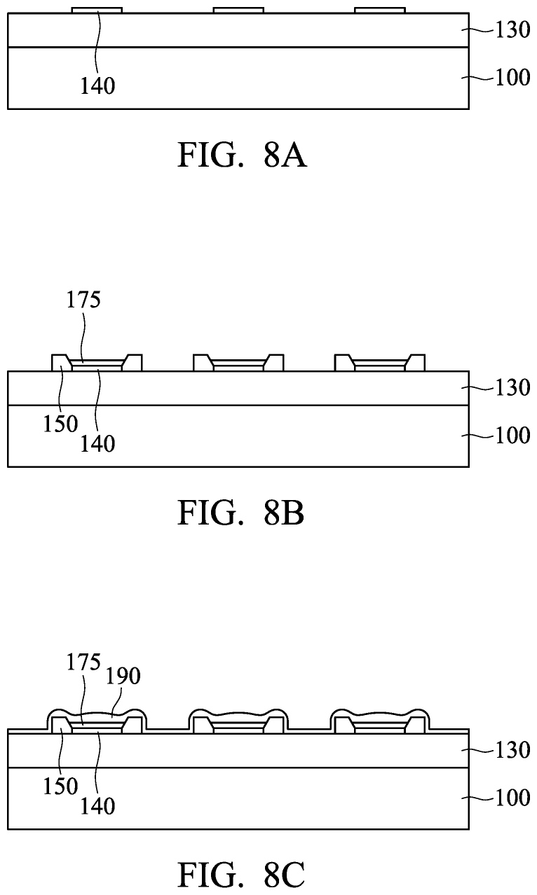

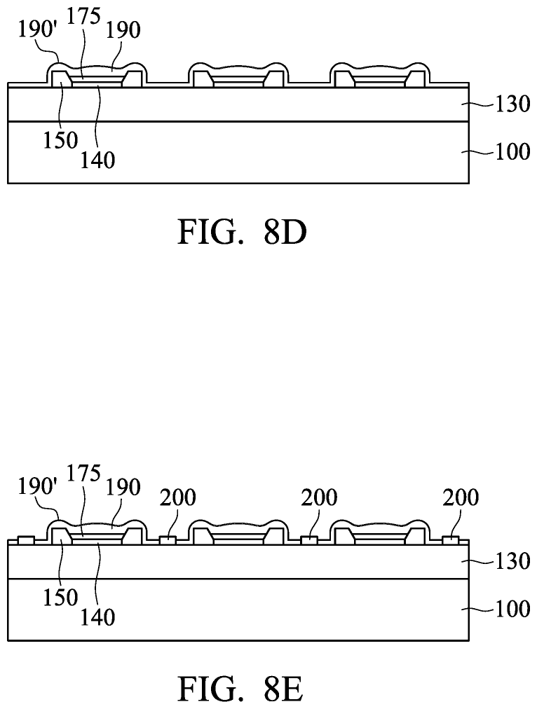

In one embodiment, an encapsulation structure is formed as shown in FIGS. 8A to 8E. The details of the flexible substrate 100, the device 130, and the electronic elements 140 in FIG. 8A are similar to those described above, and the related description is not repeated here. As shown in FIG. 8B, first partition walls 150 are formed, and the inner surfaces of the first partition walls 150 are surface treated, such that the surface energy of the inner surfaces of the first partition walls 150 is different from the surface energy of the outer surfaces of the first partition walls 150. Subsequently, a buffer layer 175 is formed by a process such as inkjet printing to cover the electronic elements 140. As shown in FIG. 8C, a solution (such as the described solution 180) is then coated, dried, and surface treated to form a gas barrier layer 190 on the surface of the described structure. As shown in FIG. 8D, another solution (such as the described solution 180) is selectively coated, dried, and surface treated to form another gas barrier layer 190′ on the surface of the gas barrier layer 190. As shown in FIG. 8E, the gas barrier layer 190 and the other gas barrier layer 190′ between the first partition walls 150 are removed to expose a top surface of the device 130, and flexible structures 200 are formed between the first partition walls 150 of different pixels or sub-pixels, thereby enhancing the flexibility of the encapsulation structure. In one embodiment, the process of removing the gas barrier layer 190 and the other gas barrier layer 190′ can be lithography and etching process, laser process, or another suitable patterning method, and the etching process can be anisotropic dry etching. It should be understood that the height of the flexible structures 200 can be higher than, equal to, or lower than the height of the first partition walls 150, as long as the flexibility of the encapsulation structure can be enhanced. Next, the flexible structures 200 may or may not contact the first partition walls 150 and/or the gas barrier layers 190 and 190′ on the basis of requirements. Although one set of buffer layer 175/gas barrier layer 190/gas barrier layer 190′ covers the single electronic element 140 in the embodiment of FIGS. 8A to 8E, it may also cover a plurality of (not all) the electronic elements 140, as described above.

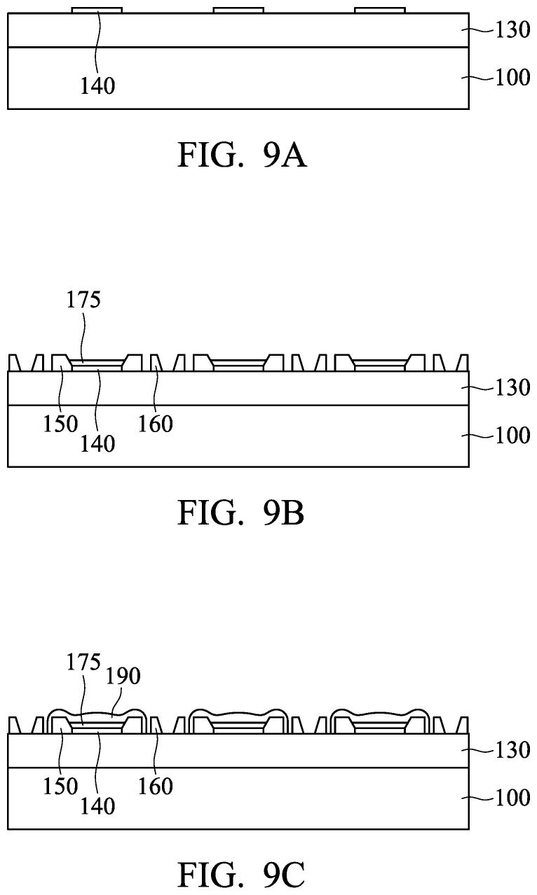

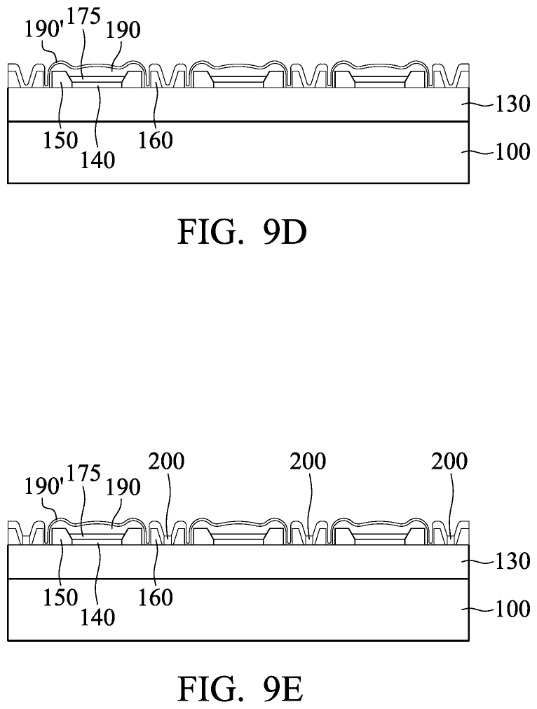

In one embodiment, an encapsulation structure is formed as shown in FIGS. 9A to 9E. The details of the flexible substrate 100, the device 130, and the electronic elements 140 in FIG. 9A are similar to those described above, and the related description is not repeated here. As shown in FIG. 9B, first partition walls 150 and second partition walls 160 are formed, and the first partition walls 150 (or the second partition walls 160) are surface treated, such that the surface energy of the first partition walls 150 is different from the surface energy of the second partition walls 160. Subsequently, a buffer layer 175 is formed by a process such as inkjet printing to cover the electronic elements 140. As shown in FIG. 9C, a solution (such as the described solution 180) is then spray coated, dried, and surface treated to form a gas barrier layer 190 on the surface of the buffer layer 175 and the first partition walls 150. As shown in FIG. 9D, another solution (such as the described solution 180) can be coated, dried, and surface treated to form another gas barrier layer 190′ on the surface of the structure in FIG. 9C. As shown in FIG. 9E, the gas barrier layer 190′ between the second partition walls 160 is removed to expose a top surface of the device 130, and flexible structures 200 are formed between the second partition walls 160 of different pixels or sub-pixels, thereby enhancing the flexibility of the encapsulation structure. In one embodiment, the process of removing the gas barrier layer 190′ can be lithography and etching process, laser process, or another suitable patterning method, and the etching process can be anisotropic dry etching. It should be understood that the height of the flexible structures 200 can be higher than, equal to, or lower than the depth of the opening (between the second partition walls 160), as long as the flexibility of the encapsulation structure can be enhanced. Next, the flexible structures 200 may or may not contact the second partition walls 160 and/or the gas barrier layer 190′ on the basis of requirements. Although one set of buffer layer 175/gas barrier layer 190/gas barrier layer 190′ covers the single electronic element 140 in the embodiment of FIGS. 9A to 9E, it may also cover a plurality of (not all) the electronic elements 140, as described above. In addition, the second partition walls 160 may be flexible structures, so that the flexible structures 200 can be omitted. As such, the electronic elements 140 can be arranged more closely by freeing up the space occupied by the flexible structures 200.

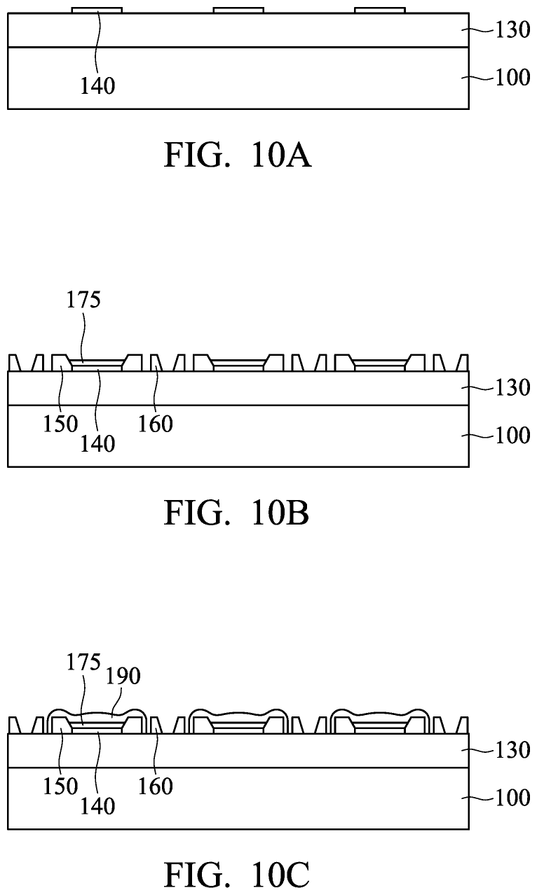

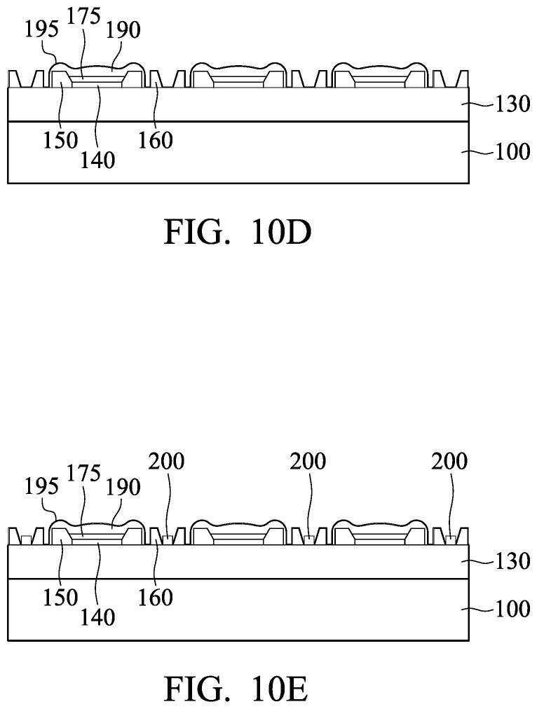

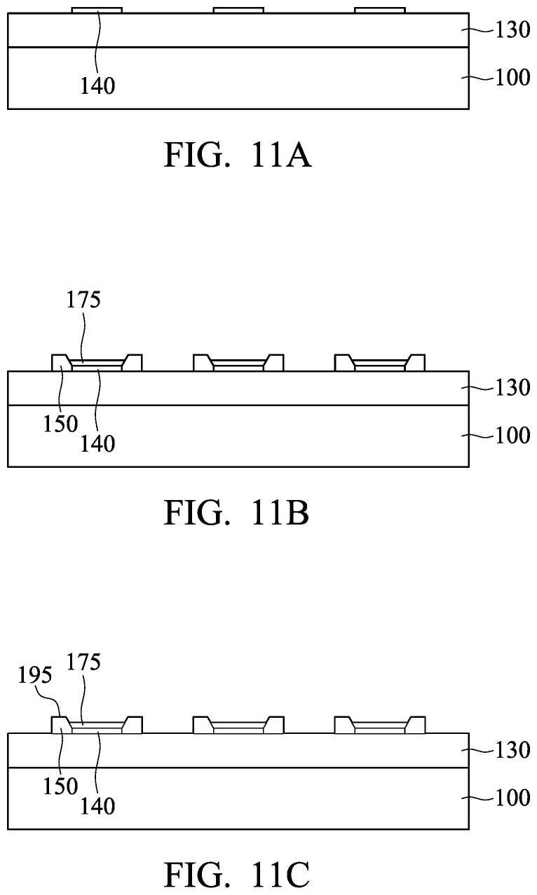

In one embodiment, an encapsulation structure is formed as shown in FIGS. 10A to 10E. The details of the flexible substrate 100, the device 130, and the electronic elements 140 in FIG. 10A are similar to those described above, and the related description is not repeated here. As shown in FIG. 10B, first partition walls 150 and second partition walls 160 are formed, and the first partition walls 150 (or the second partition walls 160) are surface treated, such that the surface energy of the first partition walls 150 is different from the surface energy of the second partition walls 160. Subsequently, a buffer layer 175 is formed by a process such as inkjet printing to cover the electronic elements 140. As shown in FIG. 10C, a solution (such as the described solution 180) is then spray coated, dried, and surface treated to form a gas barrier layer 190 on the surface of the buffer layer 175 and the first partition walls 150. As shown in FIG. 10D, a gas barrier layer 195 is formed on the surface of the structure in FIG. 10C by a process such as chemical vapor deposition, physical vapor deposition, evaporation, sputtering, or the like. In some embodiments, the gas barrier layer 195 can be silicon nitride, silicon oxide, silicon oxynitride, or the like. As shown in FIG. 10E, the gas barrier layer 195 between the second partition walls 160 is removed to expose a top surface of the device 130, and flexible structures 200 are formed between the second partition walls 160 of different pixels or sub-pixels, thereby enhancing the flexibility of the encapsulation structure. In one embodiment, the process of removing the gas barrier layer 190 and the gas barrier layer 195 can be lithography and etching process, laser process, or another suitable patterning method, and the etching process can be anisotropic dry etching. It should be understood that the height of the flexible structures 200 can be higher than, equal to, or lower than the height of the second partition walls 160, as long as the flexibility of the encapsulation structure can be enhanced. Next, the flexible structures 200 may or may not contact the second partition walls 160 and/or the gas barrier layer 195 on the basis of requirements. Although one set of buffer layer 175/gas barrier layer 190/gas barrier layer 195 covers the single electronic element 140 in the embodiment of FIGS. 9A to 9E, it may also cover a plurality of (not all) the electronic elements 140, as described above. In addition, the second partition walls 160 may be flexible structures, so that the flexible structures 200 can be omitted. As such, the electronic elements 140 can be arranged more closely by freeing up the space occupied by the flexible structures 200.

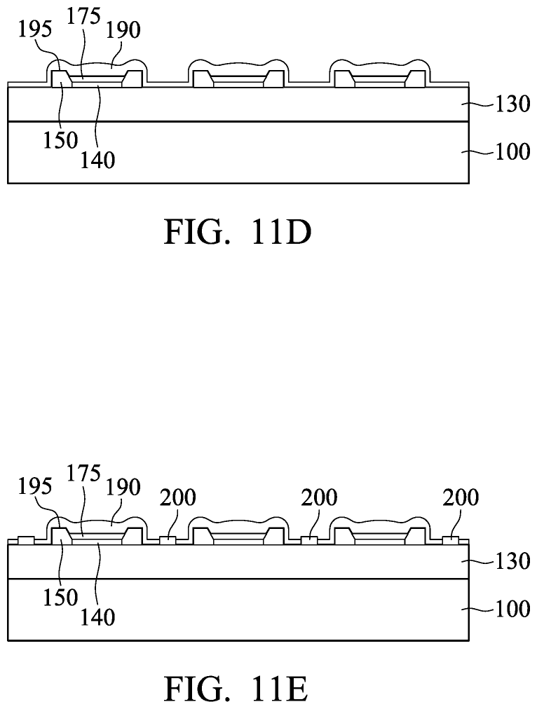

In one embodiment, an encapsulation structure is formed as shown in FIGS. 11A to 11E. The details of the flexible substrate 100, the device 130, and the electronic elements 140 in FIG. 11A are similar to those described above, and the related description is not repeated here. As shown in FIG. 11B, first partition walls 150 are formed, and inner surfaces of the first partition walls 150 are surface treated, such that the surface energy of the inner surface of the first partition walls 150 is different from the surface energy of the outer surface of the first partition walls 150. Subsequently, a buffer layer 175 is formed by a process such as inkjet printing to cover the electronic elements 140. As shown in FIG. 11C, a gas barrier layer is formed on the surface of the buffer layer 175, the first partition walls 150, and the device 130 by a process such as chemical vapor deposition, physical vapor deposition, evaporation, sputtering, or the like. As shown in FIG. 11D, a solution (such as the described solution 180) is then coated, dried, and surface treated to form a gas barrier layer 190 on the gas barrier layer 195. As shown in FIG. 11E, the gas barrier layer 195 and the gas barrier layer 190 between the first partition walls 150 are removed to expose a top surface of the device 130, and flexible structures 200 are formed between the first partition walls 150 of different pixels or sub-pixels, thereby enhancing the flexibility of the encapsulation structure. In one embodiment, the process of removing the gas barrier layer 195 and the gas barrier layer 190 can be lithography and etching process, laser process, or another suitable patterning method, and the etching process can be anisotropic dry etching. It should be understood that the height of the flexible structures 200 can be higher than, equal to, or lower than the depth of the first partition walls 150, as long as the flexibility of the encapsulation structure can be enhanced. Next, the flexible structures 200 may or may not contact the first partition walls 150 and/or the gas barrier layers 190 and 195 on the basis of requirements. Although one set of buffer layer 175/gas barrier layer 195/gas barrier layer 190 covers the single electronic element 140 in the embodiment of FIGS. 11A to 11E, it may also cover a plurality of (not all) the electronic elements 140, as described above.

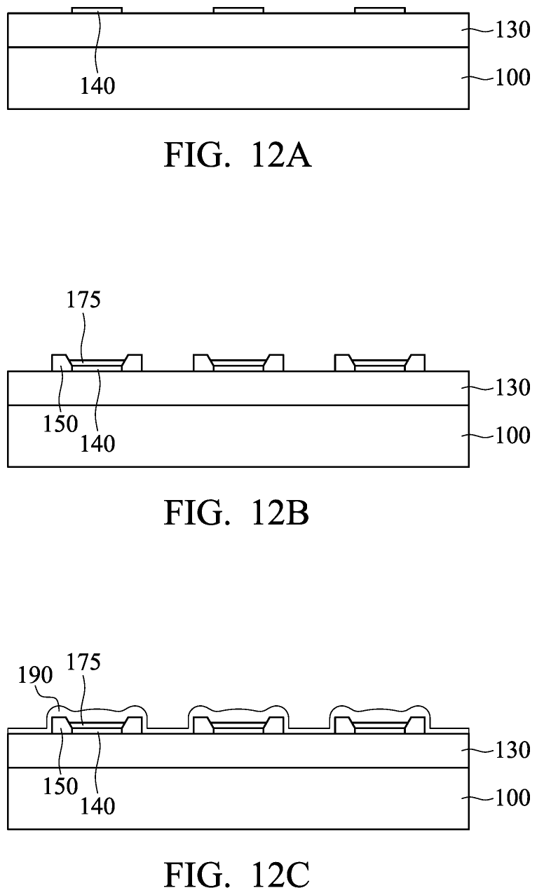

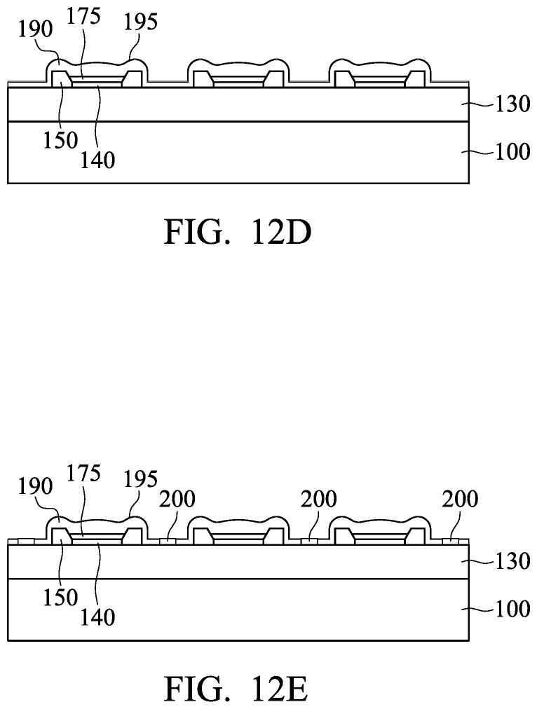

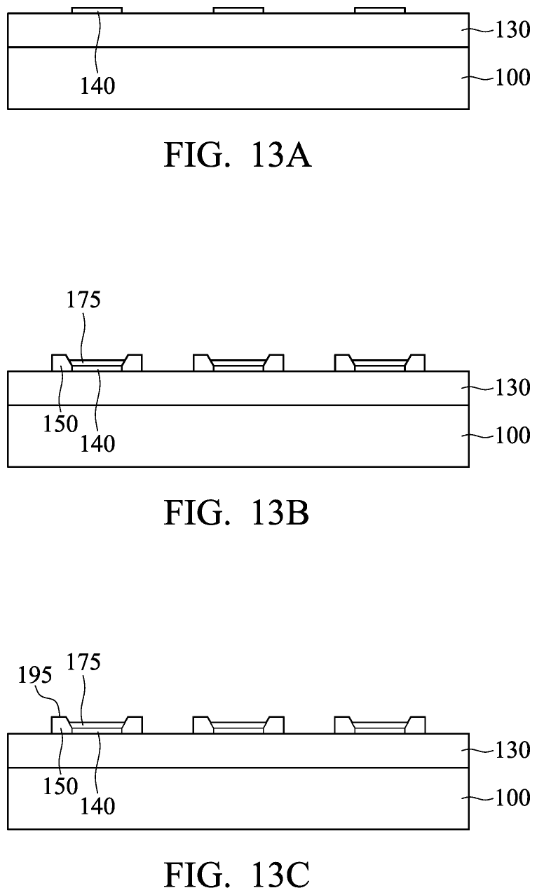

In one embodiment, an encapsulation structure is formed as shown in FIGS. 12A to 12E. The details of the flexible substrate 100, the device 130, and the electronic elements 140 in FIG. 12A are similar to those described above, and the related description is not repeated here. As shown in FIG. 12B, first partition walls 150 are formed, and inner surface of the first partition walls 150 are surface treated, such that the surface energy of the inner surface of the first partition walls 150 is different from the surface energy of the outer surface of the first partition walls 150. Subsequently, a buffer layer 175 is formed by a process such as inkjet printing to cover the electronic elements 140. As shown in FIG. 12C, a solution (such as the described solution 180) is then coated, dried, and surface treated to form a gas barrier layer 190 on the described structure. As shown in FIG. 12D, a gas barrier layer 195 is formed on the surface of the gas barrier layer 190 by a process such as chemical vapor deposition, physical vapor deposition, evaporation, sputtering, or the like. As shown in FIG. 12E, the gas barrier layer 190 and the gas barrier layer 195 between the first partition walls 150 are removed to expose a top surface of the device 130, and flexible structures 200 are formed between the first partition walls 150 of different pixels or sub-pixels, thereby enhancing the flexibility of the encapsulation structure. In one embodiment, the process of removing the gas barrier layer 190 and the gas barrier layer 195 can be lithography and etching process, laser process, or another suitable patterning method, and the etching process can be anisotropic dry etching. It should be understood that the height of the flexible structures 200 can be higher than, equal to, or lower than the depth of the first partition walls 150, as long as the flexibility of the encapsulation structure can be enhanced. Next, the flexible structures 200 may or may not contact the first partition walls 150 and/or the gas barrier layers 190 and 195 on the basis of requirements. Although one set of buffer layer 175/gas barrier layer 190/gas barrier layer 195 covers the single electronic element 140 in the embodiment of FIGS. 12A to 12E, it may also cover a plurality of (not all) the electronic elements 140, as described above.

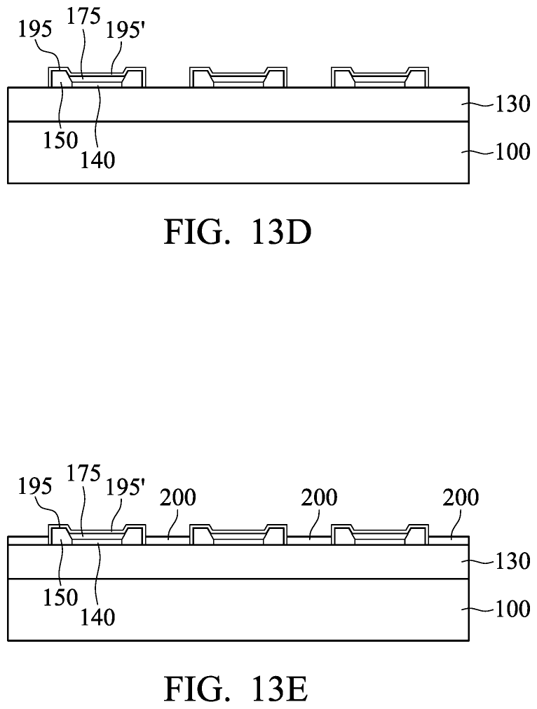

In one embodiment, an encapsulation structure is formed as shown in FIGS. 13A to 13E. The details of the flexible substrate 100, the device 130, and the electronic elements 140 in FIG. 13A are similar to those described above, and the related description is not repeated here. As shown in FIG. 13B, a buffer layer 175 is formed by a process such as inkjet printing to cover the electronic elements 140. As shown in FIG. 13C, a gas barrier layer 195 is formed on the surface of the buffer layer 175, the first partition walls 150, and the device 130 by a process such as chemical vapor deposition, physical vapor deposition, evaporation, sputtering, or the like. Subsequently, the gas barrier layer 195 not on the buffer layer 175 and the first partition walls 150 can be removed by photolithography and etching process, laser process, or another suitable patterning method. As shown in FIG. 13D, the gas barrier layer 195′ is disposed on the surface of the gas barrier layer 195 and the device 130. In one embodiment, the material selection of the gas barrier layer 195′ is similar to that of the gas barrier layer 195. The composition of the gas barrier layer 195′ can be same as or different from that of the gas barrier layer 195. In some embodiments, the gas barrier layers 195 and 195′ may be independently silicon nitride, silicon oxide, silicon oxynitride, or the like. Subsequently, the gas barrier layer 195′ not on the gas barrier layer 195 is removed, such that the remained gas barrier layer 195′ covering the gas barrier layer 195 is not connected, which does not cover the entire surface of the device 130. As shown in FIG. 13E, flexible structures 200 are then formed between the gas barrier layer 195′ of different pixels or sub-pixels, thereby enhancing the flexibility of the encapsulation structure. It should be understood that the height of the flexible structures 200 can be higher than, equal to, or lower than the depth of the opening (between the second partition walls 160), as long as the flexibility of the encapsulation structure can be enhanced. Although one set of buffer layer 175/gas barrier layer 195/gas barrier layer 195′ covers the single electronic element 140 in the embodiment of FIGS. 13A to 13E, it may also cover a plurality of (not all) the electronic elements 140, as described above. On the other hand, the flexible structures 200 can be formed after forming the buffer layer 175, rather than formed after forming the gas barrier layer 195′.

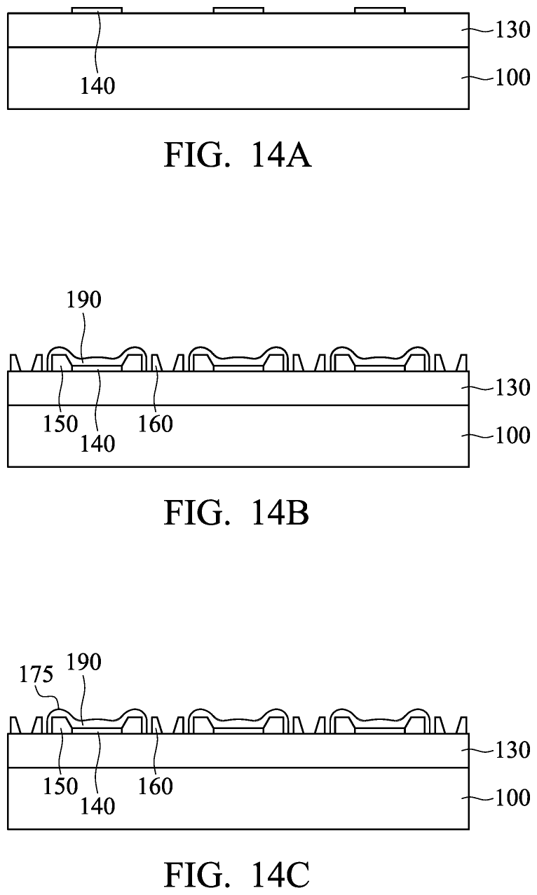

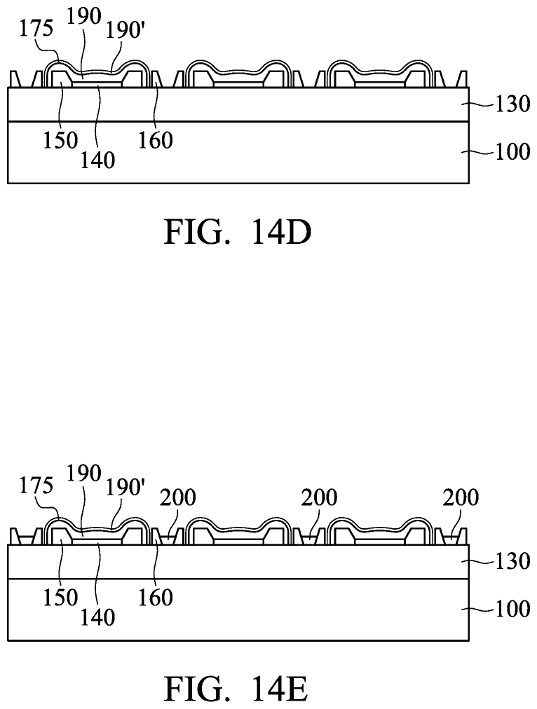

In one embodiment, an encapsulation structure is formed as shown in FIGS. 14A to 14E. The details of the flexible substrate 100, the device 130, and the electronic elements 140 in FIG. 14A are similar to those described above, and the related description is not repeated here. As shown in FIG. 14B, first partition walls 150 and second partition walls 160 are formed, and the surface of the first partition walls 150 (or the second partition walls 160) is surface treated, such that the surface energy of the first partition walls 150 is different from the surface energy of the second partition walls 160. A solution (such as the described solution 180) is spray coated, dried, and surface treated to form a gas barrier layer 190 on the surface of the electronic elements and the first partition walls 150. As shown in FIG. 14C, a buffer layer 175 is formed on the surface of the gas barrier layer 190 by a process such as inkjet printing. As shown in FIG. 14D, a solution (such as the described solution 180) is spray coated, dried, and surface treated to form a gas barrier layer 190′ on the surface of the buffer layer 175. The gas barrier layer 190 covering each of the buffer layer 175 is not connected, which does not cover the entire surface of the device 130. As shown in FIG. 14E, flexible structures 200 are then formed between the second partition walls 160 of different pixels or sub-pixels, thereby enhancing the flexibility of the encapsulation structure. It should be understood that the height of the flexible structures 200 can be higher than, equal to, or lower than the depth of the opening (between the second partition walls 160), as long as the flexibility of the encapsulation structure can be enhanced. Although one set of gas barrier layer 190/buffer layer 175/gas barrier layer 190′ covers the single electronic element 140 in the embodiment of FIGS. 14A to 14E, it may also cover a plurality of (not all) the electronic elements 140, as described above. On the other hand, the flexible structures 200 can be formed after surface treating the first partition walls 150 and/or the second partition walls 160, rather than formed after forming the gas barrier layer 190′. In addition, the second partition walls 160 may be flexible structures, so that the flexible structures 200 can be omitted. As such, the electronic elements 140 can be arranged more closely by freeing up the space occupied by the flexible structures 200.

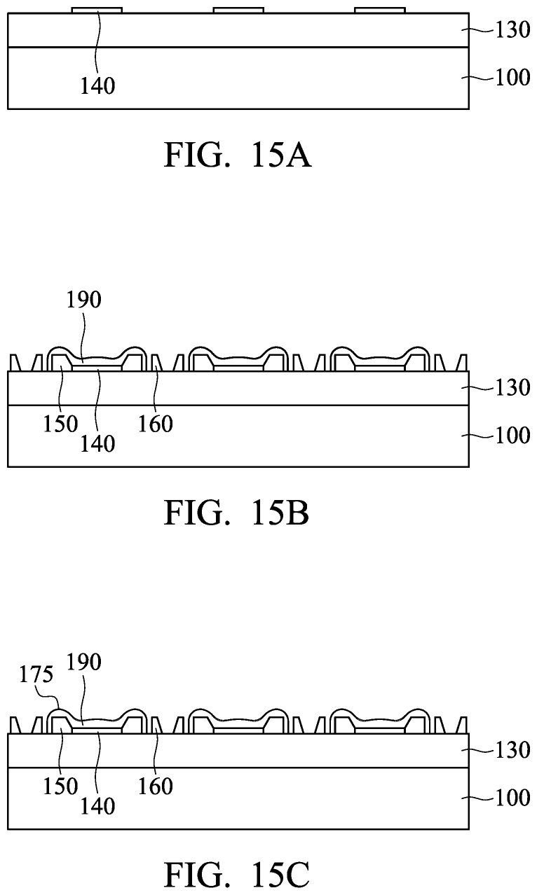

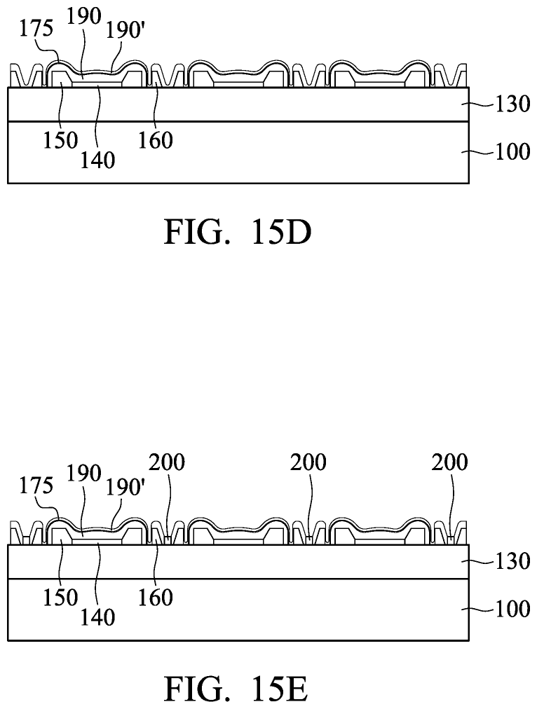

In one embodiment, an encapsulation structure is formed as shown in FIGS. 15A to 15E. The details of the flexible substrate 100, the device 130, and the electronic elements 140 in FIG. 15A are similar to those described above, and the related description is not repeated here. As shown in FIG. 15B, first partition walls 150 and second partition walls 160 are formed, and the surface of the first partition walls 150 (or the second partition walls 160) is surface treated, such that the surface energy of the first partition walls 150 is different from the surface energy of the second partition walls 160. A solution (such as the described solution 180) is spray coated, dried, and surface treated to form a gas barrier layer 190 to cover the electronic elements 140. In this step, the gas barrier layer 190 covering each of the electronic elements 140 is not connected, which does not cover the entire surface of the device 130. As shown in FIG. 15C, a buffer layer 175 is then formed on the surface of the gas barrier layer 190. The buffer layer 175 covering each of the gas barrier layer 190 is not connected, which does not cover the entire surface of the device 130. As shown in FIG. 15D, another solution (such as the described solution 180) is spray coated, dried, and surface treated to form another gas barrier layer 190′ on the described structure. As shown in FIG. 15E, the gas barrier layer 190′ between the second partition walls 160 is removed to expose a top surface of the device 130, and flexible structures 200 are formed between the second partition walls 160 of different pixels or sub-pixels, thereby enhancing the flexibility of the encapsulation structure. In one embodiment, the process of removing the gas barrier layer 190′ can be lithography and etching process, laser process, or another suitable patterning method, and the etching process can be anisotropic dry etching. It should be understood that the height of the flexible structures 200 can be higher than, equal to, or lower than the depth of the opening (between the second partition walls 160), as long as the flexibility of the encapsulation structure can be enhanced. Although one set of gas barrier layer 190/buffer layer 175/gas barrier layer 190′ covers the single electronic element 140 in the embodiment of FIGS. 15A to 15E, it may also cover a plurality of (not all) the electronic elements 140, as described above. In addition, the second partition walls 160 may be flexible structures, so that the flexible structures 200 can be omitted. As such, the electronic elements 140 can be arranged more closely by freeing up the space occupied by the flexible structures 200.

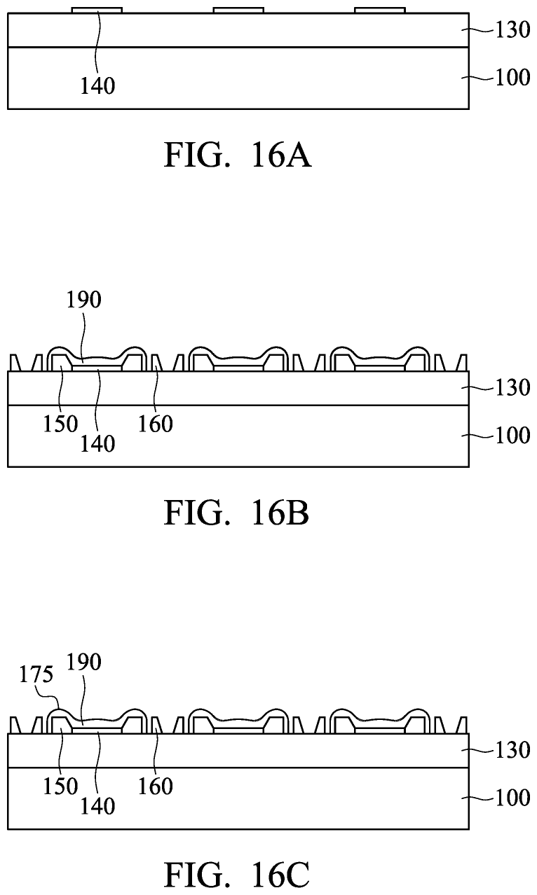

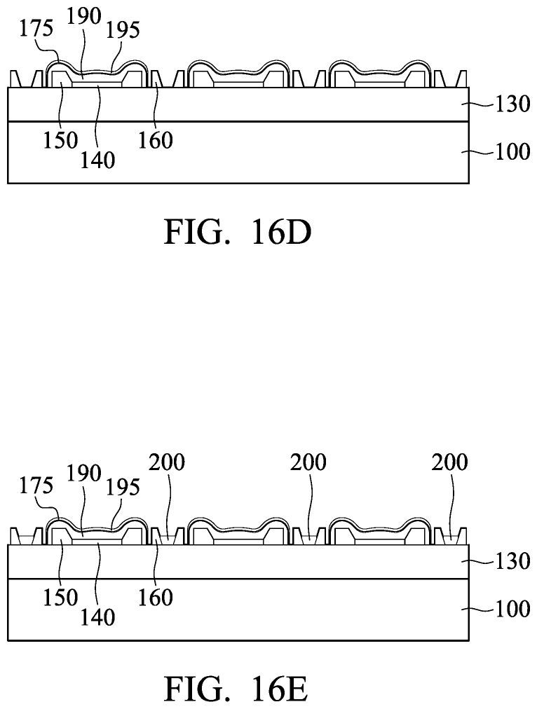

In one embodiment, an encapsulation structure is formed as shown in FIGS. 16A to 16E. The details of the flexible substrate 100, the device 130, and the electronic elements 140 in FIG. 16A are similar to those described above, and the related description is not repeated here. As shown in FIG. 16B, first partition walls 150 and second partition walls 160 are formed, and the surface of the first partition walls 150 (or the second partition walls 160) is surface treated, such that the surface energy of the first partition walls 150 is different from the surface energy of the second partition walls 160. A solution (such as the described solution 180) is spray coated, dried, and surface treated to form a gas barrier layer 190 to cover the electronic elements 140. The gas barrier layer 190 covering each of the electronic elements 140 are not connected to each other, which does not cover the entire surface of the device 130. As shown in FIG. 16C, a buffer layer 175 is then formed on the surface of the gas barrier layer 190. The buffer layer 175 covering each of the gas barrier layer 190 is not connected, which does not cover the entire surface of the device 130. As shown in FIG. 16D, a gas barrier layer 195 is formed on the surface of the buffer layer 175, the second partition walls 160, and the device 130 by a process such as chemical vapor deposition, physical vapor deposition, evaporation, sputtering, or the like. As shown in FIG. 16E, the gas barrier layer 195 between the second partition walls 160 is removed to expose a top surface of the device 130, and flexible structures 200 are formed between the second partition walls 160 of different pixels or sub-pixels, thereby enhancing the flexibility of the encapsulation structure. In one embodiment, the process of removing the gas barrier layer 195 can be photolithography and etching process, laser process, or another suitable patterning method, and the etching process can be anisotropic dry etching. It should be understood that the height of the flexible structures 200 can be higher than, equal to, or lower than the depth of the opening (between the second partition walls 160), as long as the flexibility of the encapsulation structure can be enhanced. Although one set of gas barrier layer 190/buffer layer 175/gas barrier layer 195 covers the single electronic element 140 in the embodiment of FIGS. 16A to 16E, it may also cover a plurality of (not all) the electronic elements 140, as described above. In addition, the second partition walls 160 may be flexible structures, so that the flexible structures 200 can be omitted. As such, the electronic elements 140 can be arranged more closely by freeing up the space occupied by the flexible structures 200.

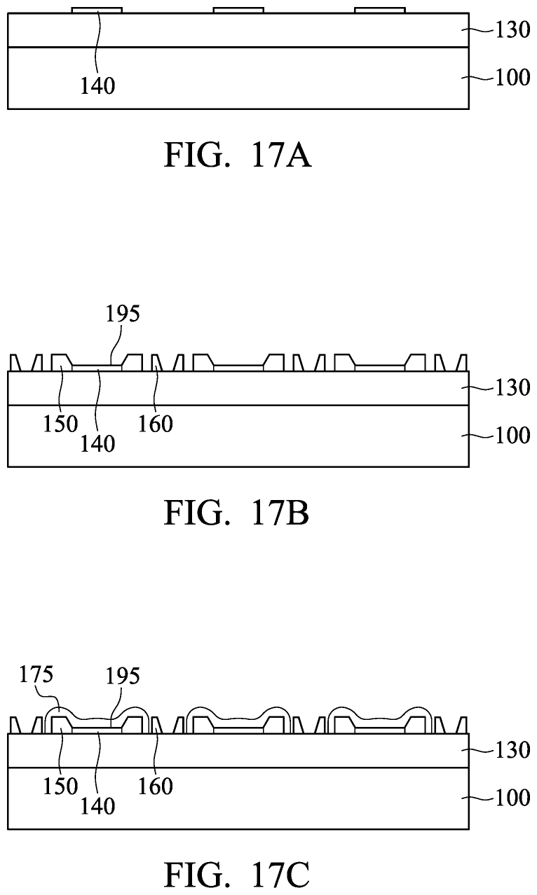

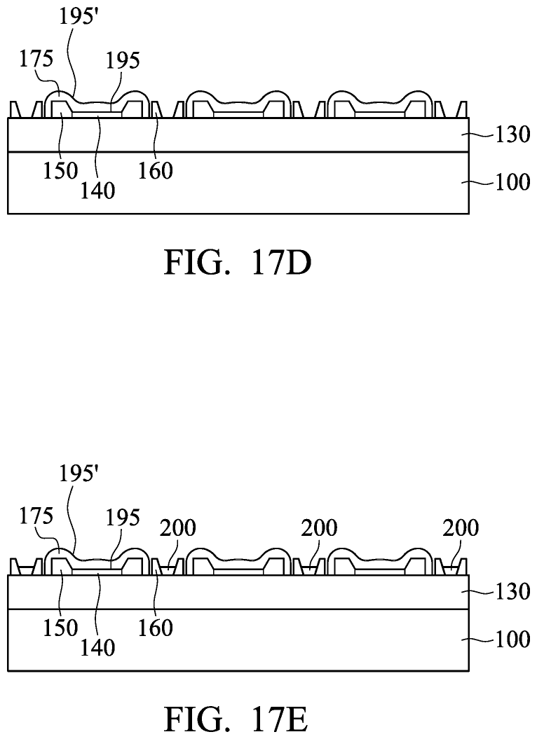

In one embodiment, an encapsulation structure is formed as shown in FIGS. 17A to 17E. The details of the flexible substrate 100, the device 130, and the electronic elements 140 in FIG. 17A are similar to those described above, and the related description is not repeated here. As shown in FIG. 17B, first partition walls 150 and second partition walls 160 are formed, and gas barrier layer 195 is then formed on the surface of the electronic elements 140, the first partition walls 150, the second partition walls 160, and the device 130 by a process such as chemical vapor deposition, physical vapor deposition, evaporation, sputtering, or the like. Subsequently, the gas barrier layer 195 not on the electronic elements 140 and the first partition walls 150 can be removed by photolithography and etching process, laser process, or another suitable patterning method. As shown in FIG. 17C, the first partition walls 150 (or the second partition walls 160) are surface treated, such that the surface energy of the first partition walls 150 is different from the surface energy of the second partition walls 160. Subsequently, a buffer layer 175 is formed on the gas barrier layer 195 by a process such as inkjet printing. As shown in FIG. 17D, a gas barrier layer 195′ is formed on the surface of the buffer layer 175, the second partition walls 160, and the device 130 by a process such as chemical vapor deposition, physical vapor deposition, evaporation, sputtering, or the like. The gas barrier layer 195′ not disposed on the buffer layer 175 is then removed, such that the gas barrier layer 195′ covering the buffer layer 175 are not connected (such as not covering the entire surface of the device 130). As shown in FIG. 17E, flexible structures 200 are then formed between the second partition walls 160 of different pixels or sub-pixels, thereby enhancing the flexibility of the encapsulation structure. It should be understood that the height of the flexible structures 200 can be higher than, equal to, or lower than the depth of the opening (between the second partition walls 160), as long as the flexibility of the encapsulation structure can be enhanced. Although one set of gas barrier layer 195/buffer layer 175/gas barrier layer 195′ covers the single electronic element 140 in the embodiment of FIGS. 17A to 17E, it may also cover a plurality of (not all) the electronic elements 140, as described above. On the other hand, the flexible structures 200 can be formed after forming the buffer layer 175, rather than formed after forming the gas barrier layer 195′.

Alternatively, only the first partition walls 150 are formed, and the inner surfaces of the first partition walls are surface treated, as shown in FIG. 8B. As such, the surface energy of the inner surfaces is different from the surface of the outer surfaces. Subsequently, a buffer layer 175 are formed by a process such as inkjet printing to cover the electronic elements 140, and the fabrication of second partition walls 160 can be omitted.

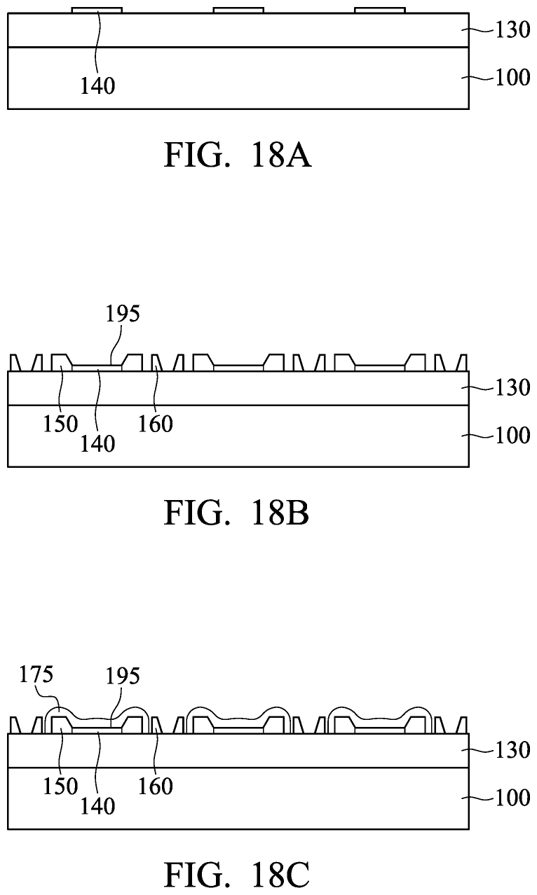

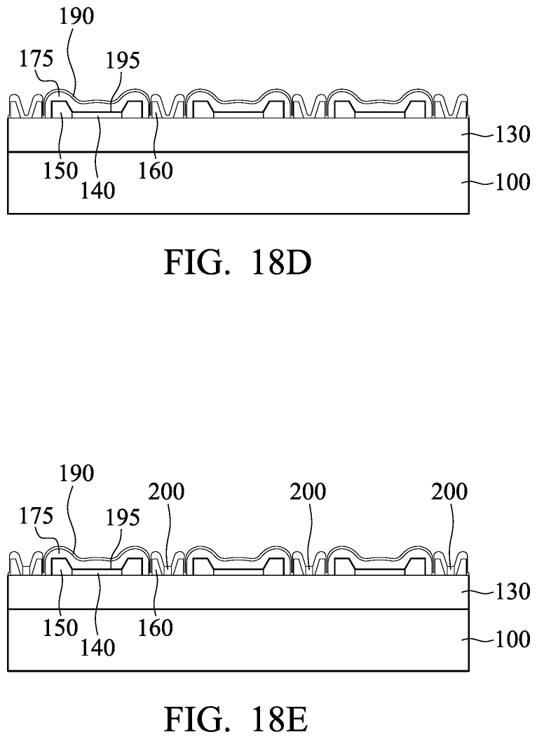

In one embodiment, an encapsulation structure is formed as shown in FIGS. 18A to 18E. The details of the flexible substrate 100, the device 130, and the electronic elements 140 in FIG. 18A are similar to those described above, and the related description is not repeated here. As shown in FIG. 18, first partition walls 150 and second partition walls 160 are formed, and a gas barrier layer 195 is formed on the surface of the electronic elements 140, the first partition walls 150, the second partition walls 160, and the device 130 by a process such as chemical vapor deposition, physical vapor deposition, evaporation, sputtering, or the like. Subsequently, the gas barrier layer 195 not on the electronic elements 140 and the first partition walls 150 is removed. As shown in FIG. 18C, the first partition walls 150 (or the second partition walls 160) are surface treated, such that the surface energy of the first partition walls 150 is different from the surface energy of the second partition walls 160. A buffer layer 175 is formed on the surface of the gas barrier layer 195 by a process such as inkjet printing. As shown in FIG. 18D, a solution (such as the described solution 180) is coated on the buffer layer 175, and then dried and surface treated to form a gas barrier layer 190 on the surface of the structure in FIG. 18C. Subsequently, the gas barrier layer 190 between the second partition walls 160 is removed. The remained gas barrier layer 190 is not connected to each other, which does not cover the entire surface of the device 130. As shown in FIG. 18E, flexible structures 200 are then formed between the second partition walls 160 of different pixels or sub-pixels, thereby enhancing the flexibility of the encapsulation structure. It should be understood that the height of the flexible structures 200 can be higher than, equal to, or lower than the depth of the opening (between the second partition walls 160), as long as the flexibility of the encapsulation structure can be enhanced. Although one set of gas barrier layer 195/buffer layer 175/gas barrier layer 190 covers the single electronic element 140 in the embodiment of FIGS. 18A to 18E, it may also cover a plurality of (not all) the electronic elements 140, as described above. On the other hand, the flexible structures 200 can be formed after forming the buffer layer 175, rather than formed after forming the gas barrier layer 190.

Alternatively, only the first partition walls 150 are formed, and the inner surfaces of the first partition walls are surface treated, as shown in FIG. 8B. As such, the surface energy of the inner surfaces is different from the surface of the outer surfaces. Subsequently, a buffer layer 175 are formed by a process such as inkjet printing to cover the electronic elements 140, and the fabrication of second partition walls 160 can be omitted.

In various embodiments of the disclosure, the gas barrier layers 190, 190′, 195, 195′, or a multi-layered structure thereof can be generalized as the first gas barrier layer of the disclosure. Alternatively, a second gas barrier layer can be selectively formed on the device region 110 before forming the electronic elements 140 in FIGS. 1 to 18E. The second gas barrier layer can be composed of a material that is similar to the gas barrier layer 190, 190′ 195, or 195′, and disposed between the flexible substrate 100 and the electronic elements 140 in the device region 110, thereby achieving the flexibility and strengthening the protection to the electronic elements 140.

One embodiment of the disclosure provides the encapsulation structure, in which the surface energy of the inner partition wall is different from (e.g. higher than) that of the surface of the outer partition wall, such that the gas barrier layer may covers the electronic elements and the surface of the inner partition wall to prevent the moisture and/or oxygen from invading and degrading the electronic elements. On the other hand, the surface energy of the inner partition wall being different from (e.g. higher than) that of the surface of the outer partition wall may reduce the risk of the solution of the gas barrier layer overflowing out of the outer partition wall during coating. Moreover, one embodiment of the disclosure provides the gas barrier layer between the flexible structure and the electronic elements, which may efficiently improve the flexibility of the encapsulation structure.

It will be apparent to those skilled in the art that various modifications and variations can be made to the disclosed embodiments. It is intended that the specification and examples be considered as exemplary only, with the true scope of the disclosure being indicated by the following claims and their equivalents.

What is claimed is:

1. An encapsulation structure, comprising:
a flexible substrate having a device region and a non-device region;
a plurality of electronic elements located in the device region of the flexible substrate;
a first partition wall surrounding one or more of the electronic elements;
a second partition wall surrounding the first partition wall, wherein the first partition wall and the second partition wall have at least one trench therebetween; and
a first gas barrier layer covering one or more of the electronic elements and the surface of the first partition wall,
wherein the surface of the first partition wall has a higher surface energy than the surface of the second partition wall.

2. The encapsulation structure as claimed in claim 1, wherein the surface energy of the first partition wall is higher than the surface energy of the second partition wall by 5 mN/m to 40 mN/m.

3. The encapsulation structure as claimed in claim 1, wherein the thickness of the first gas barrier layer and the height of the first partition wall have a ratio of 0.02:1 to 1:1.

4. The encapsulation structure as claimed in claim 1, wherein the first gas barrier layer comprises a silicon oxynitride layer, a silicon nitride layer, or a multi-layered structure thereof.

5. The encapsulation structure as claimed in claim 4, further comprising a buffer layer disposed between layers of the multi-layered structure of the first gas barrier layer, or disposed between the first gas barrier layer and the electronic elements.

6. The encapsulation structure as claimed in claim 5, wherein the thickness of the buffer layer and the thickness of the first partition wall have a ratio of 0.5:1 to 0.9:1, and the total thickness of the buffer layer and the first gas barrier layer and the height of the first partition wall have a ratio of 0.52:1 to 1:1.

7. The encapsulation structure as claimed in claim 1, wherein the first partition wall has a height of 0.1 m to 5 m, and the height of the first partition wall is equal to, higher than, or lower than the height of the second partition wall.

8. The encapsulation structure as claimed in claim 1, wherein the second partition wall comprises a flexible structure, and the second partition wall has a Young's modulus of greater than or equal to 0.2 GPa and less than 2 GPa.

9. The encapsulation structure as claimed in claim 1, wherein a top view area that is covered by the first gas barrier layer and the total area of the device region and the non-device region have a ratio of 0.01 to 0.97.

10. The encapsulation structure as claimed in claim 1, wherein the first partition wall does not surround all the electronic elements.

11. The encapsulation structure as claimed in claim 1, further comprising a second gas barrier layer disposed between the flexible substrate and the electronic elements in the device region.

12. An encapsulation structure, comprising:
a flexible substrate;
a plurality of electronic elements located on the flexible substrate;
a first gas barrier layer covering sidewalls and a top surface of one or more of the electronic elements; and
a flexible structure located on the flexible substrate, wherein the first gas barrier layer is disposed between the flexible structure and one or more of the electronic elements, and the flexible structure has a Young's modulus of greater than or equal to 0.2 GPa and less than 2 GPa.

13. The encapsulation structure as claimed in claim 12, wherein the first gas barrier layer comprises a silicon oxynitride layer, a silicon nitride layer, or a multi-layered structure thereof.

14. The encapsulation structure as claimed in claim 13, further comprising a buffer layer disposed between layers of the multi-layered structure of the first gas barrier layer, or disposed between the first gas barrier layer and the electronic elements.

15. The encapsulation structure as claimed in claim 12, wherein a top view area that is covered by the first gas barrier layer and the total area of the device region and the non-device region have a ratio of 0.01 to 0.97.

16. The encapsulation structure as claimed in claim 12, further comprising a second gas barrier layer disposed between the flexible substrate and the electronic elements in the device region.
